(19) United States
(12) Patent Application Publication
(10) Pub. No.: US 2007/0138655 A1
(43) Pub. Date: Jun. 21, 2007

(54) PAD STRUCTURE OF SEMICONDUCTOR DEVICE AND FORMATION METHOD

(76) Inventor: Young Wook Shin, Seoul (KR)

Correspondence Address: SHERR & NOURSE, PLLC, 620 HERNDON PARKWAY, SUITE 200, HERNDON, VA, 20170, US

(21) Appl. No.: 11/610,763

(22) Filed: Dec. 14, 2006

(30) Foreign Application Priority Data
Dec. 16, 2005 (KR) 10-2005-0124448

(51) Int. Cl. H01L 23/48; H01L 21/44

(52) U.S. Cl. 257/786; 438/666; 257/E23.02

(57) ABSTRACT

A bonding pad structure in a semiconductor device includes a first metal layer formed over an underlying interlayer insulating film over a semiconductor substrate, a first interlayer insulating film formed over the first metal layer, first via holes formed in the first interlayer insulating film and set apart from each other at non-uniform intervals, first vias filling the first via holes and one or more residual portions of a first via layer forming the first vias, and a second metal layer formed over the first vias and said one or more residual portions of the first via layer. The residual portions are formed together with and between the first vias due to the non-uniform intervals between the first vias.

The present application claims priority under 35 U.S.C. 119 and 35 U.S.C. 365 to Korean Patent Application No. 10-2005-0124448 (filed on Dec. 16, 2005), which is hereby incorporated by reference in its entirety.

### BACKGROUND

A semiconductor device has a bonding pad which may be connected to a bump or a wire bond for electrically connecting a chip to other devices. The bonding pad is also configured to contact probes during a test of the chip.

Referring to FIGS. 1 and 2, a pad structure includes three levels of metal layers 11, 13 and 15 and vias 21 and 25. Specifically, the first metal layer 11 is formed over an underlying insulating film 31 over a semiconductor substrate 30 to have a rectangular pattern. Then, a first interlayer insulating film 33 is deposited over the first metal layer 11, and a number of first vias 21 are formed in the first interlayer insulating film 33, wherein the first vias 21 are set apart from each other. Thereafter, a second metal layer 13 is deposited over the first interlayer insulating film 33 and the first vias 21 to have, e.g., a rectangular pattern, wherein the rectangular pattern of the second metal layer 13 is perpendicularly displaced from the rectangular pattern of the first metal layer 11. Then, a plurality of second vias 25 is formed in the second interlayer insulating film 35. The second vias 25 are set apart from each other and they are formed at locations not directly over the first vias 21. Afterwards, a third metal layer 15 is formed over the second insulating film 35 and the second vias 25 to have a rectangular pattern which is perpendicularly displaced, or directly above, the rectangular pattern of the second metal layer 13.

In the above-described pad structure and method, however, there are portions where the interlayer insulting films 33 and 35 do not precisely align and overlap with each other between the metal layers 11, 13 and 15. The planarizing process may be unstable and/or incomplete during the manufacturing process, so that photoresist, polymer, or the like might be abnormally formed over those portions. Consequently, the pad structure would suffer from foreign substances remaining thereon or suffer a color difference, which would result in pad defects.

### SUMMARY

Embodiments relate to a semiconductor device; and, more particularly, to a pad structure using a contact module made up of tungsten silicide (WSiₓ) and a formation method therefor.

Embodiments relate to a pad structure of a semiconductor device, capable of preventing process failures during the formation of a pad, and a method for forming the pad structure.

In accordance with embodiments, a pad structure of a semiconductor device includes: a first metal layer formed over an underlying interlayer insulating film, which is formed over a semiconductor substrate; a first interlayer insulating film formed over the first metal layer; first via holes formed in the first interlayer insulating film and set apart from each other at non-uniform intervals; first vias filling the first via holes and one or more residual portions of a first via layer forming the first vias, said one or more residual portions being formed together with and between the first vias due to the non-uniform intervals between the first vias; and a second metal layer formed over the first vias and said one or more residual portions of the first via layer.

In accordance with embodiments, a method of forming a pad structure of a semiconductor device includes: forming a first metal layer over an underlying interlayer insulating film, which in turn is over a semiconductor substrate; forming a first interlayer insulating film over the first metal layer; forming first via holes in the first interlayer insulating film at non-uniform intervals; forming a first via layer filling the first via holes; forming first vias filling the first via holes by planarizing the first via layer, during which one or more residual portions of the first via layer are left between the first vias due to the non-uniform intervals between the first vias; and forming a second metal layer over the first vias and said one or more residual portions of the first via layer.

### BRIEF DESCRIPTION OF THE DRAWINGS

FIGS. 1 and 2 set forth a schematic plan view and a schematic cross sectional view illustrating a pad structure of a semiconductor device.

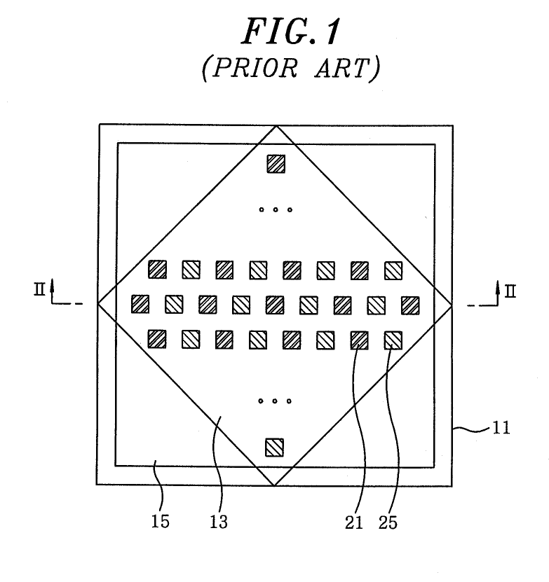

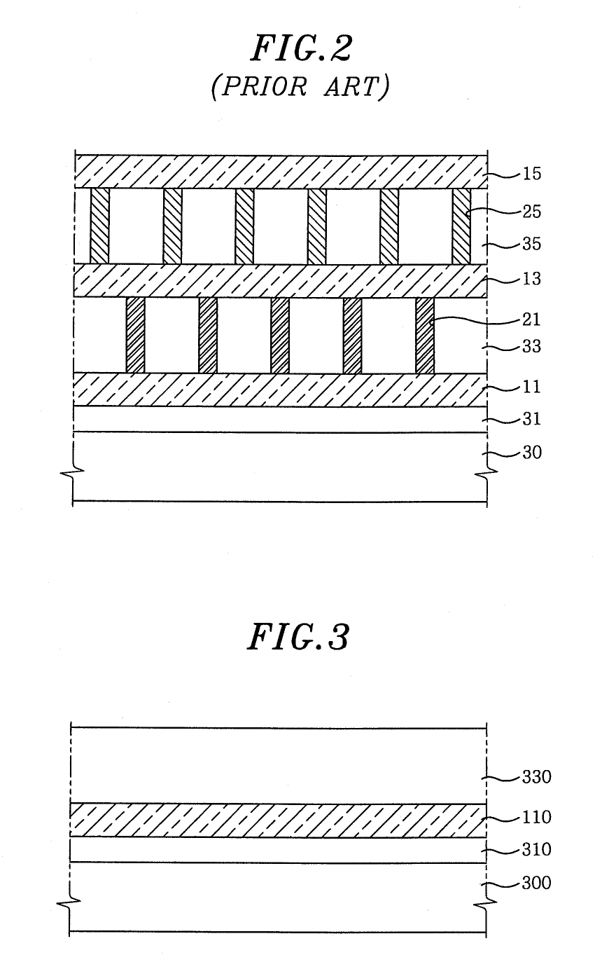

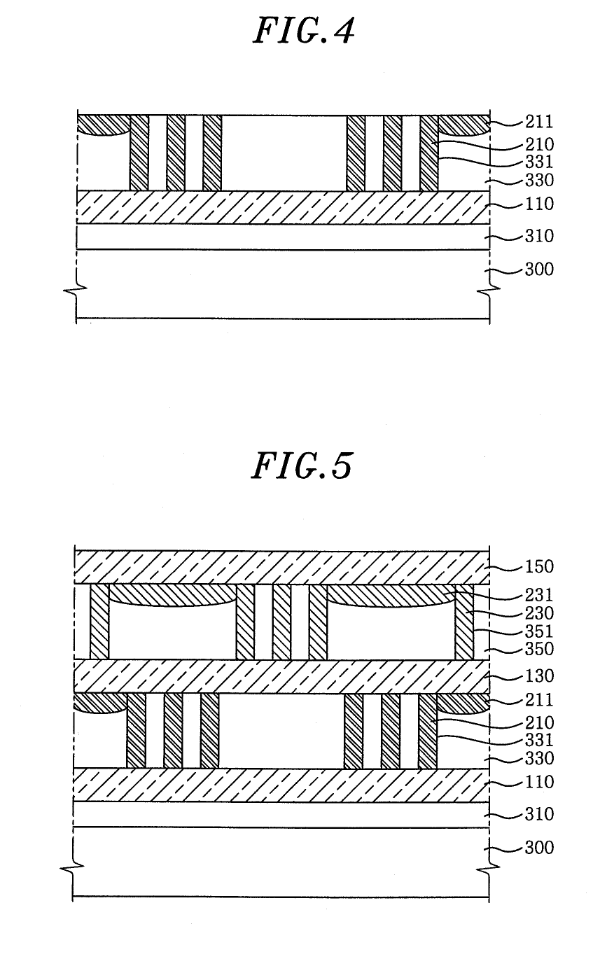

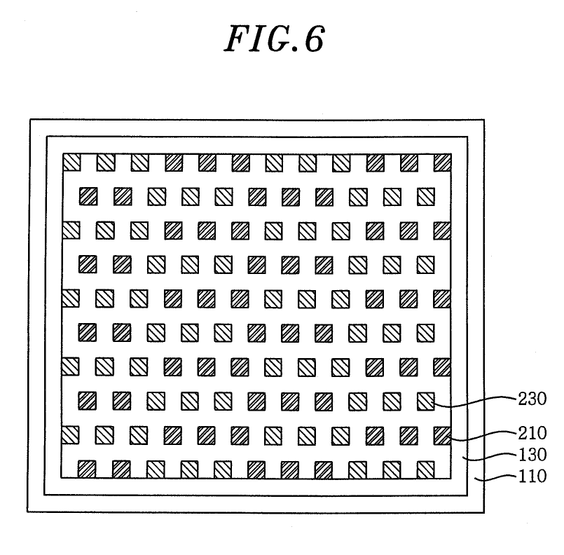

Example FIGS. 3 to 5 depict schematic cross sectional views illustrating a method for forming a pad structure of a semiconductor device, according to embodiments.

Example FIG. 6 presents a schematic plan view to describe the pad structure, in accordance with embodiments.

### DETAILED DESCRIPTION

Referring to FIG. 3, a first metal layer 110 is formed over an interlayer insulting film 310, which in turn is over a semiconductor substrate 300. Then, a first interlayer insulating film 330 is deposited over the first metal layer 110. The first interlayer insulating film 330 may be planarized through chemical mechanical polishing (CMP), an SOG etch back process, an etch back process using a photoresist pattern or the like. The planarization of the first interlayer insulating film 330 improves the quality of the subsequent second metal layer forming process and following processes thereafter. Nevertheless, since there is no extra pattern below, a pad region on which a pad is to be formed would be relatively less planarized, so the planarization of the surface of the first interlayer insulating film 330 is not sufficiently complete. That is, it is understood that the top surface of the first interlayer insulating film 330 of the pad region, on which the pad is to be formed, has protruded or recessed steps and other irregularities.

Then, referring to FIG. 4, first via holes 331 are formed in the first interlayer insulating film 330 in a manner that they are set apart from each other at non-uniform intervals. Here, though the via holes 331 may be arranged in a regular manner in some sub-regions, they are also arranged in an irregular manner in other sub-regions, so their arrangement can be understood as having an overall irregularity.

Thereafter, a first via layer for filling the first via holes 331 is formed, wherein the first via layer may be made up of a tungsten silicide film. Then, by planarizing the first via layer, the first vias 210 filling the first via holes 331 are completed. However, as a result of steps present due to the non-uniform intervals between the first vias 210, residual portions 211 of the first via layer may remain between the first vias 210. Though the presence of the residual portions 211 of the first via layer may be viewed as a disadvantage, they are intentionally left here.

Then, referring to FIG. 5, a second metal layer 130 is deposited over the first vias 210 and the residual portions 211 of the first via layer. Afterward, a second interlayer insulating film 350 is deposited over the second metal layer 130. The second interlayer insulating film 350 is planarized through chemical mechanical polishing (CMP), an SOG etch back process, an etch back process using a photoresist pattern or the like. The planarization of the second interlayer insulating film 350 is performed to improve the quality of the subsequent third metal layer forming process and any process following thereafter.

Since there is no extra pattern below, the pad region, on which a pad is to be formed, would be relatively less planarized, so the surface of the second interlayer insulating film 350 cannot be viewed to be sufficiently planarized. That is, the top surface of the first interlayer insulating film 350 of the pad region, on which the pad is to be formed, has protruded or recessed steps and/or other surface irregularities in places.

Second via holes 351 are formed in the second interlayer insulating film 350 so that they are set apart from each other at non-uniform intervals. Here, though the via holes 351 may be arranged in a regular manner in some regions, they are also arranged in an irregular manner in other regions, so their arrangement can be understood as having an overall irregularity.

Thereafter, a second via layer for filling the second via holes 351 is formed, wherein the second via layer can be made up of a tungsten silicide film. Then, by planarizing the second via layer, second vias 230 sealing the second via holes 351 are obtained. However, as a result of steps present due to the non-uniform intervals between the second vias 230, residual portions 231 of the second via layer remain among the second vias 230. Though the presence of the residual portions 231 of the second via layer might be viewed as a disadvantage in the pad forming process, they are intentionally left here.

Subsequently, a third metal layer 150 is deposited over the second vias 230 and the residual portions 231 of the second via layer. A pad structure having a planar configuration as illustrated in FIG. 6 is finally obtained.

The residual portions 211 and 231 of the via layers present between the metal layers 110, 130 and 150 improve adhesion between the metal layers 110, 130 and 150. Here, the metal layers 110, 130 and 150 can be formed in substantially rectangular-shaped patterns, as illustrated in FIG. 6, and they can be vertically aligned with each other in an orderly manner. Further, the first and the second vias 210 and 230 can be arranged not to be above or overlap each other, as shown in FIG. 6. Since their arrangement has both regularity and irregularity, overall they would be understood as being arranged irregularly. Such an irregular arrangement is intended to generate the steps, thus obtaining the residual portions 211 and 231 of the via layers.

By using extra patterns of a large pads, vias are formed with tungsten silicide in a portion where planarization tends to be done insufficiently, and residues of tungsten silicide remain between the vias. With the vias and the residues of tungsten silicide, the adhesion between the metal layers is improved, so that the problem of the metal layers being separated or peeled off can be prevented.

Further, process failures caused by the absence of overlapped portions between a lower metal layer and an upper metal layer, e.g., local color difference due to insufficient planarization, presence of residues of polymer caused by residues of cleaning solution, erosion of metal patterns, and the like can be prevented effectively.

Moreover, by using non-uniform planarization of the patterns of the pad region, it is not necessary to use a dummy pattern below the pad portion. That is, by using a short phenomenon between the vias generated due to the absence of the extra patterns after the formation of the tungsten silicide patterns, the stresses of the metal layers can be reduced, while their adhesion is enhanced. Consequently, bonding faults or defects can be effectively reduced.

It will be obvious and apparent to those skilled in the art that various modifications and variations can be made in the embodiments disclosed. Thus, it is intended that the disclosed embodiments covers the obvious and apparent modifications and variations, provided that they are within the scope of the appended claims and their equivalents.

What is claimed is:

1. A pad structure in a semiconductor device comprising:
a first metal layer formed over an underlying interlayer insulating film, the underlying interlayer insulating film formed over a semiconductor substrate;
a first interlayer insulating film formed over the first metal layer;
first via holes formed in the first interlayer insulating film and set apart from each other at non-uniform intervals;
first vias filling the first via holes and one or more residual portions of a first via layer forming the first vias, said one or more residual portions being formed together with and between the first vias due to the non-uniform intervals between the first vias; and
a second metal layer formed over the first vias and said one or more residual portions of the first via layer.

2. The pad structure of claim 1, further comprising:
a second interlayer insulating film formed over the second metal layer;
second via holes formed in the second interlayer insulating film and set apart from each other at non-uniform intervals;
second vias filling the second via holes and one or more residual portions of a second via layer forming the second vias, said one or more residual portions of the second via layer being formed together with and between the second vias due to the non-uniform intervals between the second vias; and
a third metal layer formed over the second vias and said one or more residual portions of the second via layer.

3. The pad structure of claim 2, wherein the first or the second vias comprise a tungsten silicide layer.

4. A method for forming a pad structure of a semiconductor device, comprising the steps of:
forming a first metal layer over an underlying interlayer insulating film over a semiconductor substrate;
forming a first interlayer insulating film over the first metal layer;
forming first via holes in the first interlayer insulating film at non-uniform intervals;
forming a first via layer filling the first via holes;
forming first vias filling the first via holes by planarizing the first via layer, during which one or more residual portions of the first via layer are left between the first vias due to the non-uniform intervals between the first vias; and
forming a second metal layer over the first vias and said one or more residual portions of the first via layer.

5. The method of claim 4, further comprising the steps of:
forming a second interlayer insulating film over the second metal layer;
forming second via holes in the second interlayer insulating film at non-uniform intervals;
forming a second via layer filling the second via holes;
forming second vias filling the second via holes by planarizing the second via layer, during which one or more residual portions of the second via layer are left between the second vias due to the non-uniform intervals between the second vias; and
forming a third metal layer over the second vias and said one or more residual portions of the second via layer.

6. The method of claim 4, wherein the first vias comprise a tungsten silicide layer.

7. The method of claim 5, wherein the first or the second vias comprise a tungsten silicide layer.
